(19) United States
(12) Patent Application Publication
(10) Pub. No.: US 2026/0033218 A1
(43) Pub. Date: Jan. 29, 2026

(54) DISPLAY APPARATUS AND ELECTRONIC APPARATUS INCLUDING THE DISPLAY APPARATUS

(71) Applicant: Samsung Display Co., LTD., Yongin-si (KR)

(72) Inventors: Ivan Maidanchuk, Yongin-si (KR); Mansik Myung, Yongin-si (KR); Sungjune Park, Yongin-si (KR); Jinyong Sim, Yongin-si (KR)

(21) Appl. No.: 19/276,427

(22) Filed: Jul. 22, 2025

(30) Foreign Application Priority Data
Jul. 23, 2024 (KR) 10-2024-0097493

(51) Int. Cl. H10K 59/80

(52) U.S. Cl. CPC H10K 59/873; H10K 59/879

(57) ABSTRACT

Provided is a display apparatus which includes a display panel including a display element, a window arranged on the display panel, a window protection layer arranged on the window, a hard coating layer arranged on the window protection layer, a first adhesive layer arranged between the window protection layer and the hard coating layer, and a second adhesive layer arranged between the window and the window protection layer. The display panel includes a first non-folding area, a second non-folding area, and a foldable area between the first non-folding area and the second non-folding area, the first adhesive layer includes a first-1 portion overlapping the first non-folding area, a first-2 portion overlapping the second non-folding area, and a first-3 portion overlapping the foldable area, and a thickness of the first-3 portion is greater than a thickness of each of the first-1 portion and the first-2 portion.

This application claims priority to Korean Patent Application No. 10-2024-0097493, filed on Jul. 23, 2024, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a display apparatus having improved display quality and an electronic apparatus including the display apparatus.

### 2. Description of the Related Art

Display apparatuses may be used in various electronic apparatuses. As an example, display apparatuses may be used as display screens of mobile electronic apparatuses, such as, for example, smartphones. Some display apparatuses may be foldable display apparatuses in which a portion of a display surface thereof is foldable to increase the area of the display surface while reducing an overall size.

### SUMMARY

However, in the existing display apparatuses, when the display apparatuses are folded, parts where the display apparatuses are folded deform, resulting in a deterioration in display quality.

One or more embodiments include a display apparatus having improved display quality and an electronic apparatus including the display apparatus. Embodiments set forth herein are examples, and embodiments of the disclosure are not limited thereto.

Additional aspects will be set forth in part in the description which follows and, in part, will be apparent from the description, or may be learned by practice of the presented embodiments of the disclosure.

According to one or more embodiments, a display apparatus includes a display panel including a display element, a window arranged on the display panel, a window protection layer arranged on the window, a hard coating layer arranged on the window protection layer, a first adhesive layer arranged between the window protection layer and the hard coating layer, and a second adhesive layer arranged between the window and the window protection layer, wherein the display panel includes a first non-folding area, a second non-folding area, and a foldable area between the first non-folding area and the second non-folding area, the first adhesive layer includes a first-1 portion overlapping the first non-folding area, a first-2 portion overlapping the second non-folding area, and a first-3 portion overlapping the foldable area, and a thickness of the first-3 portion is greater than a thickness of each of the first-1 portion and the first-2 portion.

The thickness of the first-3 portion may be about 250 nm to about 400 nm, and the thickness of each of the first-1 portion and the first-2 portion may be about 150 nm to about 200 nm.

The first-1 portion, the first-2 portion, and the first-3 portion may be integrally provided as a single body.

A refractive index of the first adhesive layer may be about 1.5 to about 1.6.

The second adhesive layer may include a second-1 portion overlapping the first non-folding area, a second-2 portion overlapping the second non-folding area, and a second-3 portion overlapping the foldable area, and the thicknesses of the second-1 portion, the second-2 portion, and the second-3 portion may be equal to each other.

The thickness of each of the second-1 portion, the second-2 portion, and the second-3 portion may be about 150 nm to about 200 nm, and a refractive index of the second adhesive layer may be about 1.5 to about 1.6.

According to one or more embodiments, a display apparatus includes a display panel including a display element, a window arranged on the display panel, a window protection layer arranged on the window, a hard coating layer arranged on the window protection layer, a first adhesive layer arranged between the window protection layer and the hard coating layer, and a second adhesive layer arranged between the window and the window protection layer, wherein the display panel includes a first non-folding area, a second non-folding area, and a foldable area between the first non-folding area and the second non-folding area, the second adhesive layer includes a second-1 portion overlapping the first non-folding area, a second-2 portion overlapping the second non-folding area, and a second-3 portion overlapping the foldable area, and a thickness of the second-3 portion is greater than a thickness of each of the second-1 portion and the second-2 portion.

The thickness of the second-3 portion may be about 250 nm to about 400 nm, and the thickness of each of the second-1 portion and the second-2 portion may be about 150 nm to about 200 nm.

The second-1 portion, the second-2 portion, and the second-3 portion may be integrally provided as a single body.

A refractive index of the second adhesive layer may be about 1.5 to about 1.6.

The first adhesive layer may include a first-1 portion overlapping the first non-folding area, a first-2 portion overlapping the second non-folding area, and a first-3 portion overlapping the foldable area, and the thicknesses of the first-1 portion, the first-2 portion, and the first-3 portion may be equal to each other.

The thickness of each of the first-1 portion, the first-2 portion, and the first-3 portion may be about 150 nm to about 200 nm, and a refractive index of the first adhesive layer may be about 1.5 to about 1.6.

According to one or more embodiments, a display apparatus includes a display panel including a display element, a window arranged on the display panel, a window protection layer arranged on the window, a hard coating layer arranged on the window protection layer, a first adhesive layer arranged between the window protection layer and the hard coating layer, and a second adhesive layer arranged between the window and the window protection layer, wherein the display panel includes a first non-folding area, a second non-folding area, and a foldable area between the first non-folding area and the second non-folding area, the first adhesive layer includes a first-1 portion overlapping the first non-folding area, a first-2 portion overlapping the second non-folding area, and a first-3 portion overlapping the foldable area, the second adhesive layer includes a second-1 portion overlapping the first non-folding area, a second-2 portion overlapping the second non-folding area, and a second-3 portion overlapping the foldable area, a thickness of the first-3 portion is greater than a thickness of each of the first-1 portion and the first-2 portion, and a thickness of the second-3 portion is greater than a thickness of each of the second-1 portion and the second-2 portion.

The thickness of the first-3 portion may be about 250 nm to about 400 nm, and the thickness of each of the first-1 portion and the first-2 portion may be about 150 nm to about 200 nm.

The first-1 portion, the first-2 portion, and the first-3 portion may be integrally provided as a single body.

A refractive index of the first adhesive layer may be about 1.5 to about 1.6.

The thickness of the second-3 portion may be about 250 nm to about 400 nm, and the thickness of each of the second-1 portion and the second-2 portion may be about 150 nm to about 200 nm.

The second-1 portion, the second-2 portion, and the second-3 portion may be integrally provided as a single body.

A refractive index of the second adhesive layer may be about 1.5 to about 1.6.

According to one or more embodiments, an electronic apparatus includes a display apparatus, and a housing configured to accommodate the display apparatus and form an appearance of the electronic apparatus, wherein the display apparatus includes a display panel including a display element, a window arranged on the display panel, a window protection layer arranged on the window, a hard coating layer arranged on the window protection layer, a first adhesive layer arranged between the window protection layer and the hard coating layer, and a second adhesive layer arranged between the window and the window protection layer, wherein the display panel includes a first non-folding area, a second non-folding area, and a foldable area between the first non-folding area and the second non-folding area, the first adhesive layer includes a first-1 portion overlapping the first non-folding area, a first-2 portion overlapping the second non-folding area, and a first-3 portion overlapping the foldable area, and a thickness of the first-3 portion is greater than a thickness of each of the first-1 portion and the first-2 portion.

These and/or other aspects will become apparent and more readily appreciated from the following description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of an electronic apparatus according to an embodiment;

FIG. 2 is a schematic perspective view of a display apparatus according to an embodiment;

FIG. 3 is a schematic side view of a display apparatus according to an embodiment;

FIG. 4 is a schematic cross-sectional view illustrating a cross-section of the display apparatus taken along line I-I′ of FIG. 2;

FIG. 5 is an equivalent circuit diagram of a pixel circuit included in a display panel of FIG. 4;

FIG. 6 is a schematic cross-sectional view of a portion of a display panel included in a display apparatus according to an embodiment;

FIG. 7 is a schematic cross-sectional view illustrating an enlarged portion A of the display apparatus of FIG. 4;

FIG. 8 is a graph illustrating the reflectivity of a display apparatus according to the thickness of an adhesive layer;

FIG. 9 is a graph illustrating the reflectivity of a display apparatus according to the refractive index of an adhesive layer;

FIG. 10 is a schematic cross-sectional view of a portion of a display apparatus according to an embodiment; and

FIG. 11 is a schematic cross-sectional view of a portion of a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described herein, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and embodiments thereof will be illustrated in the drawings and will be described herein in detail. The effects and features of the disclosure and the accompanying methods thereof will become apparent from the following description of the embodiments, taken in conjunction with the accompanying drawings. However, the disclosure is not limited to the embodiments described herein, and may be embodied in various modes.

In the present specification, it will be understood that although the terms “first,” “second,” and the like may be used herein to describe various elements, these elements should not be limited by these terms. These elements are used to distinguish one component from another component.

In the present specification, the singular forms “a,” “an,” and “the” are intended to include the plural forms as well, unless the context clearly indicates otherwise.

In the present specification, it will be understood that the terms “includes”, “has, “including”, and/or “having” used herein specify the presence of stated features or elements, but do not preclude the presence or addition of one or more other features or elements.

In the present specification, the expression “A and/or B” indicates A, B, or A and B. The expression “at least one of A and B” indicates A, B, or A and B.

In the present specification, it will be understood that when a layer, region, or component is referred to as being “formed on” another layer, region, or component, it can be directly or indirectly formed on the other layer, region, or component. That is, for example, intervening layers, regions, or components may be present.

In the present specification, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. For example, in the present specification, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

In the present specification, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel. The term “substantially flat” means approximately or actually flat. The term “substantially planarize” means approximately or actually planarize.

Hereinafter, example embodiments will be described in detail with reference to the accompanying drawings, and in the description with reference to the drawings, the same or corresponding constituents are indicated by the same reference numerals and redundant descriptions thereof are omitted. Sizes of components in the drawings may be exaggerated for convenience of description. For example, since sizes and thicknesses of components in the drawings are arbitrarily illustrated for convenience of description, the following embodiments are not limited thereto.

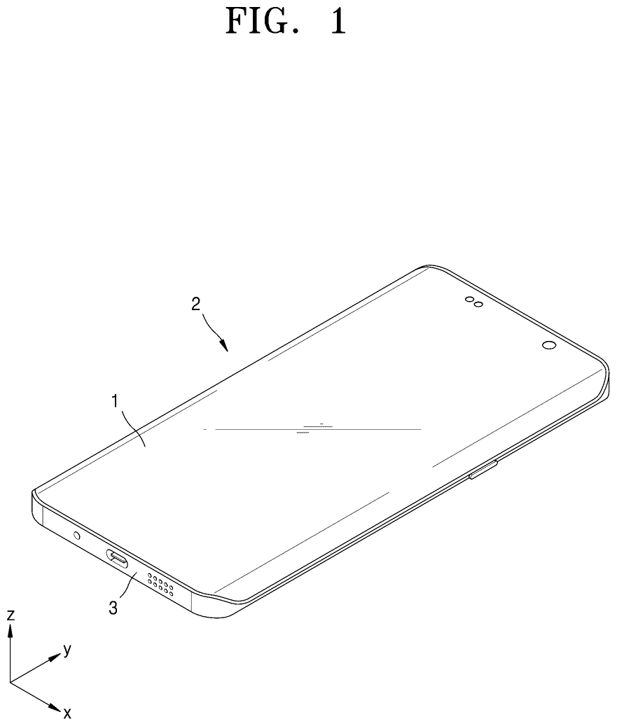

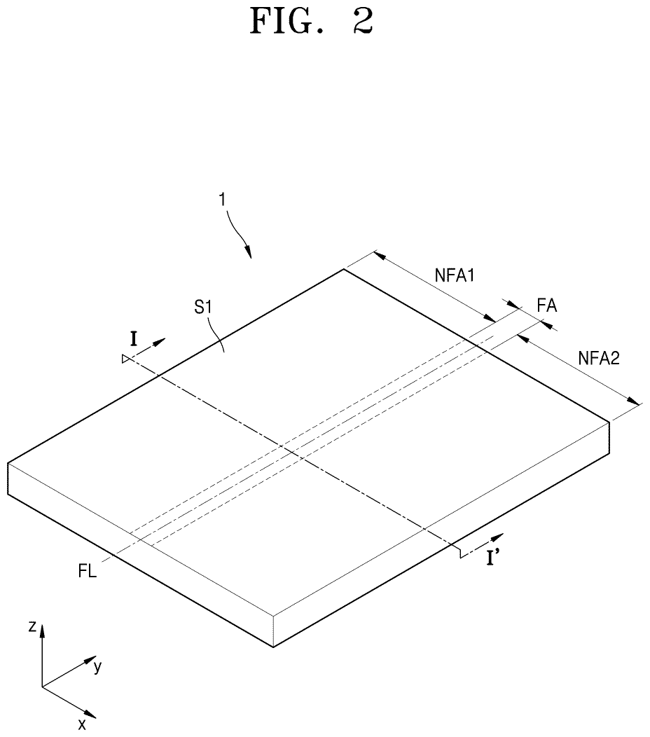

FIG. 1 is a schematic perspective view of an electronic apparatus 2 according to an embodiment. FIG. 2 is a schematic perspective view of a display apparatus 1 according to an embodiment.

As illustrated in FIGS. 1 and 2, the display apparatus 1 may display a moving image or a still image, may display a screen, or perform input and output of data in the electronic apparatus 2.

Although it is illustrated in FIG. 1 that the display apparatus 1 is used in a mobile phone as an example, the disclosure is not limited thereto. For example, the display apparatus 1 may be used as a display screen for various electronic apparatuses, such as, for example, a television, a laptop, a monitor, a billboard, and an Internet of things (IoT) device, as well as mobile electronic apparatuses, such as, for example, a mobile phone, a smartphone, a tablet personal computer (PC), a mobile communication terminal, an electronic notebook, an electronic book, a portable multimedia player (PMP), a navigation system, and an ultra mobile PC (UMPC).

In an embodiment, the display apparatus 1 may be used in electronic apparatuses such as, for example, wearable devices, for example, smart watches, watch phones, eyeglass displays, and head mounted displays (HMDs). In an embodiment, the display apparatus 1 may be used as a display for various electronic apparatuses, such as, for example, a center information display (CID) placed on a dashboard of an automobile and a center fascia or dashboard of an automobile, a room mirror display replacing a side mirror of an automobile, or a display placed on the back of a front seat as entertainment for passengers on the rear seat of an automobile.

In an embodiment, the display apparatus 1 may be accommodated in a housing 3 of the electronic apparatus 2. The housing 3 may be a cover that protects internal components, such as, for example, the display apparatus 1, and forms the appearance of the electronic apparatus 2. For example, the housing 3 may form the exterior of the electronic apparatus 2. In some aspects, the display apparatus 1 may be connected to an electronic module of the electronic apparatus 2 and driven on the electronic apparatus 2. Hereinafter, the description will focus on the display apparatus 1.

As illustrated in FIG. 2, the display apparatus 1 may have a polygonal shape including a quadrangle. For example, the display apparatus 1 may have a rectangular shape having a horizontal length shorter than a vertical length, a rectangular shape having a horizontal length longer than a vertical length, or a square shape. Alternatively, the display apparatus 1 may have various shapes, such as, for example, an oval or a circle. Although it is illustrated in FIG. 1 that the display apparatus 1 has a rectangular shape having a horizontal length shorter than a vertical length, the disclosure is not limited thereto.

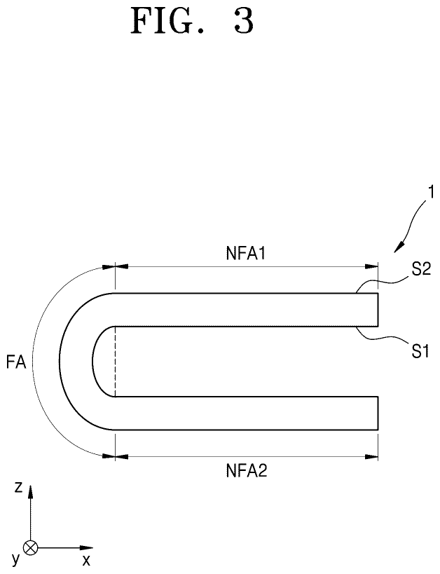

The display apparatus 1 may include a first surface S1 and a second surface S2 (see FIG. 3) opposite to the first surface S1. The display apparatus 1 may display an image on the first surface S1. That is, the first surface S1 may include a display surface. In an embodiment, the first surface S1 may be the upper surface (in the +z direction) of the display apparatus 1. The second surface S2 may be the lower surface (in the −z direction) of the display apparatus 1. In some embodiments, the second surface S2 may include a display surface, and the display apparatus 1 may display an image on the second surface S2.

The display apparatus 1 may be foldable. That is, at least a portion of the display apparatus 1 may be flexible, and as the flexible portion is bent, the display apparatus 1 may be folded. For example, as illustrated in FIG. 3, which is a schematic side view of the display apparatus 1 according to an embodiment, the display apparatus 1 may be folded. That is, FIG. 2 is a perspective view illustrating an unfolded state of the display apparatus 1, and FIG. 3 is a side view illustrating a folded state of the display apparatus 1.

Accordingly, the display apparatus 1 may include a folding area and a non-folding area provided on at least one side of the folding area. In the present specification, “non-folding” means not folding, which includes not only a case of not being flexible and hard to be folded, but also a case of having flexibility but not being folded. The display apparatus 1 may display an image not only in the non-folding area but also in the folding area.

As illustrated in FIG. 2, the display apparatus 1 may include a first non-folding area NFA1, a second non-folding area NFA2, and a foldable area FA. The first non-folding area NFA1 and the second non-folding area NFA2 may be areas that are not folded, and the foldable area FA may be a flexible area that may be folded.

The foldable area FA may extend in a direction crossing an imaginary straight line connecting the first non-folding area NFA1 to the second non-folding area NFA2. Specifically, when the display apparatus 1 is in an unfolded state, the first non-folding area NFA1 and the second non-folding area NFA2 may be arranged apart from each other in a first direction (e.g., the x direction or the −x direction). The foldable area FA may be between the first non-folding area NFA1 and the second non-folding area NFA2. Specifically, the first non-folding area NFA1 may be adjacent to one side of the foldable area FA, and the second non-folding area NFA2 may be adjacent to the other side of the foldable area FA. In an example in which the display apparatus 1 is in an unfolded state, the foldable area FA may extend in a second direction (e.g., the y direction or the −y direction) crossing the first direction.

A folding line FL may be provided in the foldable area FA in the second direction (e.g., the y direction or the −y direction) that is an extending direction of the foldable area FA. Accordingly, the display apparatus 1 may be folded in the foldable area FA. The foldable area FA and the folding line FL of the foldable area FA may overlap an area where an image of the display apparatus 1 is displayed, and when the display apparatus 1 is folded, a portion displaying an image may be folded.

For convenience of description, it is illustrated in FIG. 2 that the first non-folding area NFA1 and the second non-folding area NFA2 have the same or similar areas and the display apparatus 1 has one foldable area FA. However, the disclosure is not limited thereto. For example, the first non-folding area NFA1 and the second non-folding area NFA2 may have different areas. In some aspects, the display apparatus 1 may include a plurality of foldable areas FA. In this case, a plurality of non-folding areas may be apart from each other, and each of the plurality of foldable areas FA may be between the non-folding areas. Each foldable area FA may be folded based on the folding line FL, and a plurality of folding lines FL may be provided.

It is illustrated in FIG. 2 that the folding line FL passes through the center of the foldable area FA and the foldable area FA is line-symmetric with respect to the folding line FL. However, the disclosure is not limited thereto. For example, the folding line FL may be provided asymmetrically in the foldable area FA.

As illustrated in FIG. 3, the display apparatus 1 may be folded such that the first surface S1 of the first non-folding area NFA1 and the first surface S1 of the second non-folding area NFA2 face each other based on the folding line FL. In other words, as the foldable area FA of the display apparatus 1 is bent, the first surface S1 of the first non-folding area NFA1 and the first surface S1 of the second non-folding area NFA2 may be arranged to face each other. Even when the display apparatus 1 is folded, the foldable area FA may extend in a direction crossing an imaginary straight line connecting the first non-folding area NFA1 to the second non-folding area NFA2. Specifically, when the display apparatus 1 is folded, the foldable area FA may extend in the second direction (e.g., the y direction or the −y direction) crossing an imaginary straight line (e.g., a straight line parallel to the z-axis direction) connecting the first non-folding area NFA1 to the second non-folding area NFA2. The foldable area FA may be unfolded again after being bent. That is, the display apparatus 1 may be a foldable display apparatus. Although not illustrated in FIG. 1, the housing 3 of the electronic apparatus 2 may include a hinge or the like such that the display apparatus 1 may be folded even when the display apparatus 1 is accommodated in the housing 3 of the electronic apparatus 2.

In the present specification, the term “folded” means that the shape is not fixed and is transformed from an original shape to another shape, for example, the term means that the foldable area FA is folded, curved, or bent along one or more specific lines, that is, the folding line FL. The term “foldable” means that the shape is not fixed and is transformable from an original shape to another shape, for example, the term means that the foldable area FA is foldable or bendable along one or more specific lines, that is, the folding line FL. Therefore, although FIG. 3 illustrates a folded state in which the first surface S1 of the first non-folding area NFA1 and the first surface S1 of the second non-folding area NFA2 are arranged parallel to each other and face each other, the disclosure is not limited thereto. For example, the display apparatus 1 may be folded such that the first surface S1 of the first non-folding area NFA1 and the first surface S1 of the second non-folding area NFA2 form a certain angle (e.g., an acute angle, a right angle, or an obtuse angle) with the foldable area FA between the first surface S1 of the first non-folding area NFA1 and the first surface S1 of the second non-folding area NFA2.

In some aspects, although it is illustrated in FIG. 3 that the display apparatus 1 is folded (i.e., in-folded) such that a portion of the first surface S1 and another portion of the first surface S1 face each other, the disclosure is not limited thereto. For example, the display apparatus 1 may be folded (i.e., out-folded) such that a portion of the second surface S2 and another portion of the second surface S2 face each other. In other words, the display apparatus 1 may be in an in-folding form in which the display surface is folded such that portions of the display surface face each other when the display apparatus 1 is folded, or in an out-folding form in which the display surface is exposed to the outside when the display apparatus 1 is folded. Hereinafter, for convenience of description, the case in which the display apparatus 1 is in an in-folding form will be described.

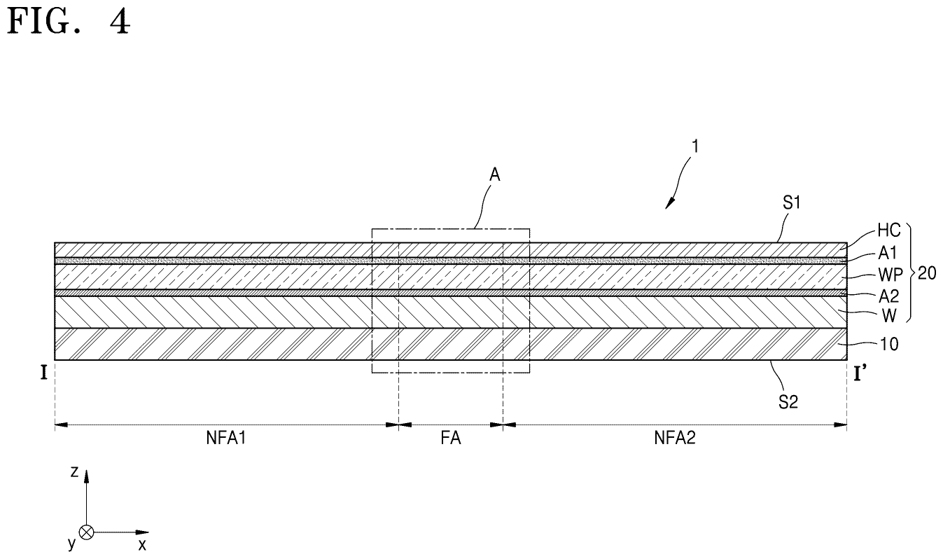

FIG. 4 is a schematic cross-sectional view illustrating a cross-section of the display apparatus 1 taken along line I-I′ of FIG. 2. The display apparatus 1 may include a display panel 10 and a cover window 20.

The display panel 10 may display images. To this end, the display panel 10 may include a plurality of display elements, and the plurality of display elements may emit light. Accordingly, the display panel 10 may display an image through light emitted from the plurality of display elements. In an embodiment, the display element may be an organic light-emitting diode including an organic emission layer. Alternatively, the display element may be a light-emitting diode (LED). The LED may have a size of a micro scale or a nano scale. For example, the LED may be a micro LED. Alternatively, the LED may be a nanorod LED. The nanorod LED may include gallium nitride (GaN). In an embodiment, a color conversion layer may be arranged on the nanorod LED. The color conversion layer may include quantum dots. Alternatively, the display element may be a quantum dot LED including a quantum dot emission layer. Alternatively, the display element may be an inorganic LED including an inorganic semiconductor. Detailed descriptions of components included in the display panel 10 will be described later.

As described herein, the display apparatus 1 may include a first non-folding area NFA1, a second non-folding area NFA2, and a foldable area FA. Because the display apparatus 1 includes the display panel 10, it may be stated that the display panel 10 has the first non-folding area NFA1, the second non-folding area NFA2, and the foldable area FA, as described herein. Hereinafter, for convenience, the display panel 10 will be described as having the first non-folding area NFA1, the second non-folding area NFA2, and the foldable area FA.

The cover window 20 may be arranged on the display panel 10. Specifically, the cover window 20 may be arranged on the upper surface (in the +z direction) of the display panel 10. In this case, the ‘upper surface’ of the display panel 10 may be defined as a surface facing a direction in which the display panel 10 provides an image. The cover window 20 may be arranged such that the cover window 20 covers the upper surface of the display panel 10 and thus may have a function of protecting the upper surface of the display panel 10. The image displayed by the display panel 10 may be provided to the user through the cover window 20. That is, the image provided by the display apparatus 1 may be understood as being implemented by the display panel 10.

The cover window 20 may have high transmittance to transmit light emitted from the display panel 10 and may have a small thickness to reduce the weight of the display apparatus 1. In some aspects, the cover window 20 may have a strength (e.g., relatively high strength) and a hardness supportive of protecting the display panel 10 from external impact. The cover window 20 may include a window W, a window protection layer WP, a hard coating layer HC, a first adhesive layer A1, and a second adhesive layer A2.

Specifically, the window W may be arranged on the display panel 10. The window W may include glass, sapphire, or plastic. For example, the window W may be ultra-thin glass (UTG®) of which the strength is increased by a method such as, for example, chemical strengthening or thermal strengthening, or may be colorless polyimide (CPI). The window W may have a structure in which a flexible polymer layer is arranged on one side of a glass substrate. In some other embodiments the window W may have a structure composed only of a polymer layer.

In an embodiment, the window W may have a refractive index of about 1.3 to about 1.7. The window W may have a thickness of about 30 μm to about 70 μm.

The window protection layer WP may be arranged on the window W. The window protection layer WP may protect the window W and prevent or reduce scratches from occurring on the upper surface (in the +z direction) of the window W. In an embodiment, the window protection layer WP may include a polymer resin. For example, the window protection layer WP may include at least one of polymer resins, such as, for example, polyethyleneterephthalate (PET), poly(butylene terephthalate) (PBT), polycarbonate (PC), polyethylene naphthalate (PEN), polystyrene (PS), polymethylmethacrylate (PMMA), polyvinylchloride (PVC), polyethersulfone (PES), polypropylene (PP), and polyamide (PA).

In an embodiment, the window protection layer WP may have a refractive index of about 1.5 to about 1.7. The window protection layer WP may have a thickness of about 30 μm or about 70 μm.

The hard coating layer HC may be arranged on the window protection layer WP. The hard coating layer HC may be the outermost layer of the cover window 20. That is, the hard coating layer HC may be the outermost layer of the display apparatus 1. The hard coating layer HC may be a layer that a user directly touches, and the hard coating layer HC may have a surface which is smooth and soft to the touch. In some aspects, the hard coating layer HC may increase the strength and hardness of the cover window 20. In an embodiment, the hard coating layer HC may include a polymer resin. For example, the hard coating layer HC may include a silicone-based polymer. However, the material of the hard coating layer HC is not particularly limited, and the hard coating layer HC may include a known hard coating material.

In an embodiment, the hard coating layer HC may have a refractive index of about 1.4 to about 1.5. The hard coating layer HC may have a thickness of about 3 μm to about 7 μm.

Adhesive layers may be arranged between components of the cover window 20 and combine the components of the cover window 20. Specifically, a first adhesive layer A1 may be arranged between the window protection layer WP and the hard coating layer HC, and a second adhesive layer A2 may be arranged between the window W and the window protection layer WP. That is, the hard coating layer HC may be attached to the window protection layer WP by the first adhesive layer A1, and the window protection layer WP may be attached to the window W by the second adhesive layer A2.

The first adhesive layer A1 and the second adhesive layer A2 may each include an adhesive member, such as, for example, an optically clear adhesive (OCA) or a pressure sensitive adhesive (PSA). As the adhesive member, general ones known in the art may be employed without limitation. In an embodiment, the first adhesive layer A1 may have a refractive index of about 1.5 to about 1.6. In an embodiment, the second adhesive layer A2 may have a refractive index of about 1.5 to about 1.6. The thickness of at least one of the adhesive layers may be different between the non-folding area and the foldable area FA. Specifically, at least one of the adhesive layers may have a larger thickness in the foldable area FA than in the non-folding area. A detailed description of the thicknesses of the adhesive layers will be provided later.

Although not illustrated in FIG. 4, an adhesive member may be arranged between the display panel 10 and the cover window 20. The cover window 20 may be attached to the display panel 10 through the adhesive member. As the adhesive member, general ones known in the art may be employed without limitation. For example, the adhesive member may be an OCA or a PSA.

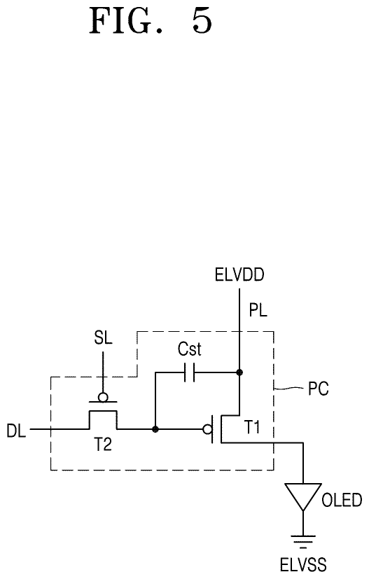

FIG. 5 is an equivalent circuit diagram of a pixel circuit PC included in the display panel 10 of FIG. 4. The pixel circuit PC may be electrically connected to a display element, and the display element may correspond to a pixel. In FIG. 5, an organic light-emitting diode OLED is illustrated as the display element. In an embodiment, the display element may emit red, green, or blue light.

The pixel circuit PC may include a first transistor T1, a second transistor T2, and a storage capacitor Cst. The second transistor T2 is a switching transistor and is connected to a scan line SL and a data line DL. The second transistor T2 may be configured to turn on based on a switching signal input from the scan line SL and transfer a data signal input from the data line DL to the first transistor T1. The storage capacitor Cst has one end electrically connected to the second transistor T2 and the other end electrically connected to a driving voltage line PL. The storage capacitor Cst may be configured to store a voltage corresponding to a difference between a voltage received from the second transistor T2 and a driving power supply voltage ELVDD supplied to the driving voltage line PL.

The first transistor T1 is a driving transistor and is connected to the driving voltage line PL and the storage capacitor Cst. The first transistor T1 may be configured to control the amount of driving current flowing from the driving voltage line PL to the organic light-emitting diode OLED in response to a voltage value stored in the storage capacitor Cst. The organic light-emitting diode OLED may emit light having a certain luminance by the driving current. An opposite electrode of the organic light-emitting diode OLED may receive an electrode power supply voltage ELVSS.

Although FIG. 5 illustrates that the pixel circuit PC includes two transistors and one storage capacitor, the disclosure is not limited thereto. For example, the number of transistors or storage capacitors may be variously changed depending on the design of the pixel circuit PC.

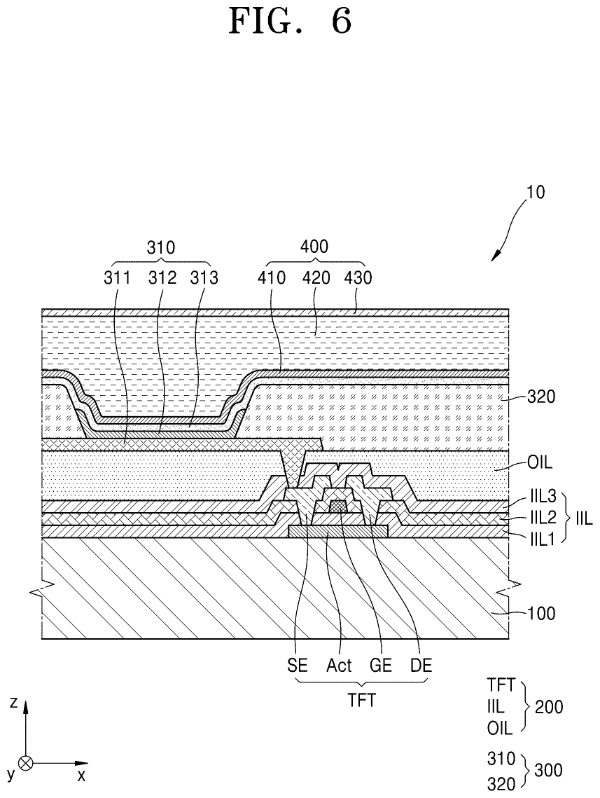

FIG. 6 is a schematic cross-sectional view of a portion of the display panel 10 included in the display apparatus 1 according to an embodiment. As will be recognized by those of ordinary skill in the art, the display panel 10 may further include various other components in addition to the configuration illustrated in FIG. 6.

As illustrated in FIG. 6, the display panel 10 may include a substrate 100, and a transistor and a display element formed by several layers formed on the substrate 100. Specifically, the display panel 10 may include a substrate 100, a pixel circuit layer 200, a display element layer 300, and an encapsulation layer 400.

The substrate 100 may include glass, metal or polymer resin. The substrate 100 may be implemented as being flexible or bendable. In this case, the substrate 100 may include a polymer resin, such as, for example, polyethersulphone, polyacrylate, polyetherimide, polyethylenenaphthalate, polyethyleneterephthalate, polyphenylenesulfide, polyarylate, polyimide, polycarbonate, or cellulose acetate propionate. In some aspects, the substrate 100 may be variously modified. For example, the substrate 100 may have a multi-layered structure including two layers including the polymer resin and a barrier layer including an inorganic material (e.g., silicon oxide (SiO_{X}), silicon nitride (SiN_{X}), or silicon oxynitride (SiO_{X}N_{Y})) between the two layers.

The pixel circuit layer 200 may be arranged on the substrate 100. The pixel circuit layer 200 may include a transistor TFT, an inorganic insulating layer IIL, and an organic insulating layer OIL. The transistor TFT may include a semiconductor layer Act, a gate electrode GE, a source electrode SE, and a drain electrode DE. The inorganic insulating layer IIL may include a gate insulating layer IIL1, a first interlayer insulating layer IIL2, and a second interlayer insulating layer IIL3. For convenience of illustration, one transistor TFT is illustrated in FIG. 6. The transistor TFT may correspond to the first transistor T1 described herein.

The semiconductor layer Act may be arranged on the substrate 100. The semiconductor layer Act may include polysilicon. Alternatively, the semiconductor layer Act may include amorphous silicon, an oxide semiconductor, or an organic semiconductor. In an embodiment, the semiconductor layer Act may include a channel region and a source region and a drain region respectively arranged on both sides of the channel region.

The gate insulating layer IIL1 may be arranged on the semiconductor layer Act and the substrate 100. The gate insulating layer IIL1 may include an inorganic insulating material, such as, for example, silicon oxide (SiO_{X}), silicon nitride (SiN_{X}), silicon oxynitride (SiO_{X}N_{Y}), aluminum oxide (Al₂O₃), titanium oxide (TiO_{X}), tantalum oxide (Ta₂O₅), hafnium oxide (HfO₂), or zinc oxide (ZnOx). Zinc oxide (ZnO_{X}) may include zinc oxide (ZnO) and/or zinc peroxide (ZnO₂).

The gate electrode GE may be arranged on the gate insulating layer IIL1. That is, as the gate insulating layer IIL1 is between the semiconductor layer Act and the gate electrode GE, insulation between the semiconductor layer Act and the gate electrode GE may be secured. The gate electrode GE may overlap the channel region of the semiconductor layer Act. The gate electrode GE may include a low-resistance metal material. In an embodiment, the gate electrode GE may include a conductive material including molybdenum (Mo), aluminum (Al), copper (Cu), titanium (Ti), or the like and may have a single-layered or multi-layered structure including the conductive material.

The first interlayer insulating layer IIL2 may be arranged on the gate electrode GE and the gate insulating layer IIL1. The first interlayer insulating layer IIL2 may include an inorganic insulating material, such as, for example, SiO_{X}, SiN_{X}, SiO_{X}N_{Y}, Al₂O₃, TiO_{X}, Ta₂O₅, HfO₂, or ZnO_{X}.

The source electrode SE and the drain electrode DE may be arranged on the first interlayer insulating layer IIL2. Each of the source electrode SE and the drain electrode DE may be connected to the semiconductor layer Act through a contact hole formed in the gate insulating layer IIL1 and the first interlayer insulating layer IIL2. At least one of the source electrode SE and the drain electrode DE may include a conductive material including Mo, Al, Cu, Ti, or the like and may have a single-layered or multi-layered structure including the conductive material. In an embodiment, at least one of the source electrode SE and the drain electrode DE may have a multi-layered structure including Ti/Cu/Ti layers.

The second interlayer insulating layer IIL3 may be arranged on the source electrode SE, the drain electrode DE, and the first interlayer insulating layer IIL2. The second interlayer insulating layer IIL3 may include an inorganic insulating material, such as, for example, SiO_{X}, SiN_{X}, SiO_{X}N_{Y}, Al₂O₃, TiO_{X}, Ta₂O₅, HfO₂, or ZnOx.

The organic insulating layer OIL may be arranged on the second interlayer insulating layer IIL3. The organic insulating layer OIL may substantially planarize an upper surface of the pixel circuit layer 200. The organic insulating layer OIL may include an organic material, such as, for example, acrylic, benzocyclobutene (BCB), or hexamethyldisiloxane (HMDSO). Although it is illustrated in FIG. 6 that the organic insulating layer OIL includes a single layer, various modifications, such as, for example, multiple layers, may be made.

The display element layer 300 may be arranged on the pixel circuit layer 200. The display element layer 300 may include a display element 310 and a pixel-defining layer 320. The display element 310 may be electrically connected to the transistor TFT. The display element 310 may be, for example, an organic light-emitting diode having a pixel electrode 311, an opposite electrode 313, and an intermediate layer 312 placed between the pixel electrode 311 and the opposite electrode 313 and including an emission layer. The fact that the display element 310 is electrically connected to the transistor TFT may be understood as the fact that the pixel electrode 311 of the organic light-emitting diode is electrically connected to the transistor TFT.

The pixel electrode 311 may contact either the source electrode SE or the drain electrode DE through a contact hole formed in the second interlayer insulating layer IIL3 and the organic insulating layer OIL and be electrically connected to the transistor TFT. The pixel electrode 311 may include a conductive oxide, such as, for example, indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 311 may include a reflective layer including silver (Ag), magnesium (Mg), aluminum (Al), platinum (Pt), palladium (Pd), gold (Au), nickel (Ni), neodymium (Nd), iridium (Ir), chromium (Cr) or a compound thereof. In another embodiment, the pixel electrode 311 may further include a layer including ITO, IZO, ZnO, or In₂O₃ above/below the reflective layer.

The pixel-defining layer 320 may cover an edge of the pixel electrode 311. The pixel-defining layer 320 may have a pixel opening, and the pixel opening may overlap the pixel electrode 311. The pixel opening may define an emission area of light emitted from the display element 310. The pixel-defining layer 320 may include an organic insulating material and/or an inorganic insulating material. In some embodiments, the pixel-defining layer 320 may include a light blocking material.

The intermediate layer 312 may be arranged on the pixel electrode 311 and the pixel-defining layer 320. The intermediate layer 312 may include a low molecular weight or high molecular weight material. In an example in which the intermediate layer 312 includes a low molecular weight material, the intermediate layer 312 may have a structure in which a hole injection layer (HIL), a hole transport layer (HTL), an emission layer (EML), an electron transport layer (ETL), an electron injection layer (EIL), or the like are stacked in a single or complex structure, and may be formed by a vacuum deposition method. In an example in which the intermediate layer 312 includes a high molecular weight material, the intermediate layer 312 may have a structure including an HTL and an EML. In this case, the HTL may include PEDOT, and the EML may include a high molecular weight material, such as, for example, polyphenylene vinylene (PPV) or polyfluorene

The intermediate layer 312 may be formed by screen printing, inkjet printing, laser induced thermal imaging (LITI), or the like. However, the intermediate layer 312 is not necessarily limited thereto and may have various structures. Furthermore, the intermediate layer 312 may include a layer across a plurality of pixel electrodes 311 or may include a layer patterned to correspond to each of the plurality of pixel electrodes 311.

The opposite electrode 313 may be arranged on the intermediate layer 312 and the pixel-defining layer 320. The opposite electrode 313 may be integrally formed in a plurality of organic light-emitting diodes to correspond to a plurality of pixel electrodes 311. The opposite electrode 313 may include a light-transmitting conductive layer including ITO, In₂O₃, or IZO, and may also include a semi-transmission layer including a metal, such as, for example, Al or Ag. For example, the opposite electrode 313 may be a semi-transmission layer including Mg or Ag.

The display element 310 may be easily damaged by moisture or oxygen from the outside, and thus, the encapsulation layer 400 may cover the display element 310 to protect the display element 310. Referring to FIG. 6, the encapsulation layer 400 may include a first inorganic encapsulation layer 410, an organic encapsulation layer 420, and a second inorganic encapsulation layer 430.

The first inorganic encapsulation layer 410 may cover the opposite electrode 313 and may include SiO_{X}, SiN_{X}, and/or SiO_{X}N_{Y}. As applicable based on implementation in accordance with one or more embodiments of the present disclosure, other layers, such as, for example, a capping layer, may be between the first inorganic encapsulation layer 410 and the opposite electrode 313. Because the first inorganic encapsulation layer 410 is formed along a structure thereunder, the upper surface of the first inorganic encapsulation layer 410 may not be flat, as illustrated in FIG. 6. The organic encapsulation layer 420 may cover the first inorganic encapsulation layer 410, and unlike the first inorganic encapsulation layer 410, the upper surface of the organic encapsulation layer 420 may be substantially flat. The organic encapsulation layer 420 may include one or more materials selected from the group consisting of polyethyleneterephthalate, polyethylenenaphthalate, polycarbonate, polyimide, polyethylenesulfonate, polyoxymethylene, polyarylate, and hexamethyldisiloxane. The second inorganic encapsulation layer 430 may cover the organic encapsulation layer 420 and may include SiO_{X}, SiN_{X}, and/or SiO_{X}N_{Y}.

As described herein, the encapsulation layer 400 includes the first inorganic encapsulation layer 410, the organic encapsulation layer 420, and the second inorganic encapsulation layer 430, and thus, even when a crack occurs in the encapsulation layer 400 through the multi-layered structure, the crack may be disconnected between the first inorganic encapsulation layer 410 and the organic encapsulation layer 420 or between the organic encapsulation layer 420 and the second inorganic encapsulation layer 430. Accordingly, the formation of a path through which moisture or oxygen from the outside penetrates the display panel 10 may be prevented or reduced.

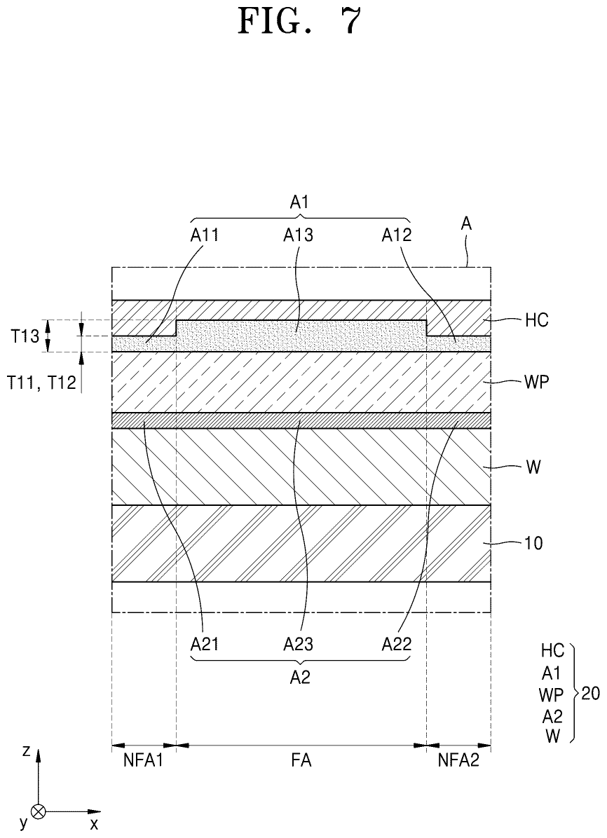

FIG. 7 is a schematic cross-sectional view illustrating an enlarged portion A of the display apparatus 1 of FIG. 4. As described herein, the thickness of at least one of the first adhesive layer A1 and the second adhesive layer A2 may be different between the non-folding area and the foldable area FA. Specifically, at least one of the first adhesive layer A1 and the second adhesive layer A2 may have a larger thickness in the foldable area FA than in the non-folding area.

As illustrated in FIG. 7, the first adhesive layer A1 may include a first-1 portion A11, a first-2 portion A12, and a first-3 portion A13. The first-1 portion A11 may be arranged on the first non-folding area NFA1, the first-2 portion A12 may be arranged on the second non-folding area NFA2, and the first-3 portion A13 may be arranged on the foldable area FA In other words, the first-1 portion A11 may overlap the first non-folding area NFA1, the first-2 portion A12 may overlap the second non-folding area NFA2, and the first-3 portion A13 may overlap the foldable area FA. The first-1 portion A11, the first-2 portion A12, and the first-3 portion A13 may be integrally provided as a single body.

Similarly, the second adhesive layer A2 may include a second-1 portion A21, a second-2 portion A22, and a second-3 portion A23. The second-1 portion A21 may be arranged on the first non-folding area NFA1, the second-2 portion A22 may be arranged on the second non-folding area NFA2, and the second-3 portion A23 may be arranged on the foldable area FA. In other words, the second-1 portion A21 may overlap the first non-folding area NFA1, the second-2 portion A22 may overlap the second non-folding area NFA2, and the second-3 portion A23 may overlap the foldable area FA. The second-1 portion A21, the second-2 portion A22, and the second-3 portion A23 may be integrally provided as a single body.

The thickness of the first-3 portion A13 may be greater than the thickness of each of the first-1 portion A11 and the first-2 portion A12. In the present specification, the thickness of a portion means the length of a corresponding portion in a thickness direction (e.g., the z-axis direction) of the display apparatus 1. Specifically, the first-1 portion A11 may have a first-1 thickness T11, the first-2 portion A12 may have a first-2 thickness T12, and the first-2 thickness T12 may be the same as or similar to the first-1 thickness T11. The first-3 portion A13 may have a first-3 thickness T13, and the first-3 thickness T13 may be greater than each of the first-1 thickness T11 and the first-2 thickness T12.

For example, each of the first-1 thickness T11 and the first-2 thickness T12 may be about 150 nm to about 200 nm, and the first-3 thickness T13 may be about 250 nm to about 400 nm. In this case, the reflectivity of the foldable area FA of the display apparatus 1 may be less than the reflectivity of the non-folding area of the display apparatus 1. Specifically, light incident on the display apparatus 1 may be reflected at interfaces between components of the display apparatus 1. Therefore, by adjusting the thickness and refractive index of at least some of the components of the display apparatus 1, the light reflected at the interfaces between the components of the display apparatus 1 may be destructively interfered. Accordingly, the reflectivity of the light incident on the display apparatus 1 may be reduced. Specifically, the reflectivity of the foldable area FA of the display apparatus 1 may be about 5.5% to about 6.5%, and the reflectivity of the non-folding area of the display apparatus 1 may be about 6.3% to about 6.8%.

As described herein, the display apparatus 1 includes a display panel 10 and a cover window 20, and the cover window 20 includes a window W, a window protection layer WP, a hard coating layer HC, a first adhesive layer A1, and a second adhesive layer A2. Because the display panel 10, the window W, the window protection layer WP, and the hard coating layer HC are very thick compared to the adhesive layers, a change in the thicknesses of layers corresponding thereto may not have a significant effect on the reflectivity of light incident on the display apparatus 1. However, because the first adhesive layer A1 and the second adhesive layer A2 are very thin compared to the display panel 10, the window W, the window protection layer WP, and the hard coating layer HC, the first adhesive layer A1 and the second adhesive layer A2 may have a significant effect on the reflectivity of light incident on the display apparatus 1.

In general, when the display apparatus 1 is folded, the foldable area FA of the display apparatus 1 may be deformed. Specifically, when the display apparatus 1 is folded, the foldable area FA of the display apparatus 1 is bent, and thus, compressive stress or tensile stress may be applied to the foldable area FA. The foldable area FA may be deformed by the compressive stress or tensile stress. The deformed foldable area FA may not be restored to its original shape even when the display apparatus 1 is unfolded again. That is, a crease may be formed in the foldable area FA of the display apparatus 1.

However, in the case of the display apparatus 1 according to the present embodiment, the thickness of at least one of the first adhesive layer A1 and the second adhesive layer A2 may be different between the non-folding area and the foldable area FA. Specifically, at least one of the first adhesive layer A1 and the second adhesive layer A2 may have a larger thickness in the foldable area FA than in the non-folding area. Accordingly, the reflectivity of the foldable area FA of the display apparatus 1 may be less than the reflectivity of the non-folding area of the display apparatus 1. Because the reflectivity of the foldable area FA is less than the reflectivity of the non-folding area of the display apparatus 1, the crease in the foldable area FA may be less visible to the user. Therefore, the display quality of the display apparatus 1 may be improved.

In an embodiment, the thickness of the second-3 portion A23 may be the same as or similar to the thickness of each of the second-1 portion A21 and the second-2 portion A22. That is, the thicknesses of the second-1 portion A21, the second-2 portion A22, and the second-3 portion A23 may be the same as or similar to each other. Specifically, the thickness of each of the second-1 portion A21, the second-2 portion A22, and the second-3 portion A23 may be about 150 nm to about 200 nm.

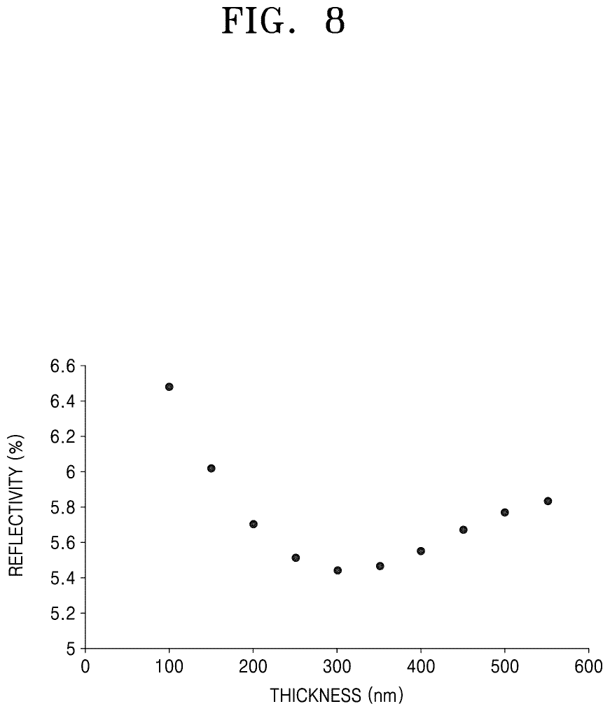

FIG. 8 is a graph illustrating the reflectivity of the display apparatus 1 according to the thickness of an adhesive layer. Specifically, FIG. 8 is a graph illustrating the reflectivity of the foldable area FA according to the thickness of the first-3 portion A13. That is, the horizontal axis of the graph of FIG. 8 represents the thickness of the first-3 portion A13, and the vertical axis of the graph of FIG. 8 represents the reflectivity of the foldable area FA of the display apparatus 1. The refractive index of the first adhesive layer A1 is 1.50. The refractive index of the window W is 1.50, and the thickness of the window W is 50 μm. The refractive index of the window protection layer WP is 1.60, and the thickness of the window protection layer WP is 50 μm. The refractive index of the hard coating layer HC is 1.45, and the thickness of the hard coating layer HC is 5 μm. The refractive index of the second adhesive layer A2 is 1.50, and the thickness of the second adhesive layer A2 is 200 nm.

As illustrated in FIG. 8, when the thickness of the first-3 portion A13 is about 250 nm to about 400 nm, the reflectivity of the foldable area FA is the lowest. In contrast, for example, when the thickness of the first-3 portion A13 is less than 250 nm or more than 400 nm, the reflectivity of the foldable area FA rapidly increases. Because the thickness of each of the first-1 portion A11 and the first-2 portion A12 is about 150 nm to about 200 nm, when the thickness of the first-3 portion A13 is about 250 nm to about 400 nm, the crease of the foldable area FA may be less visible.

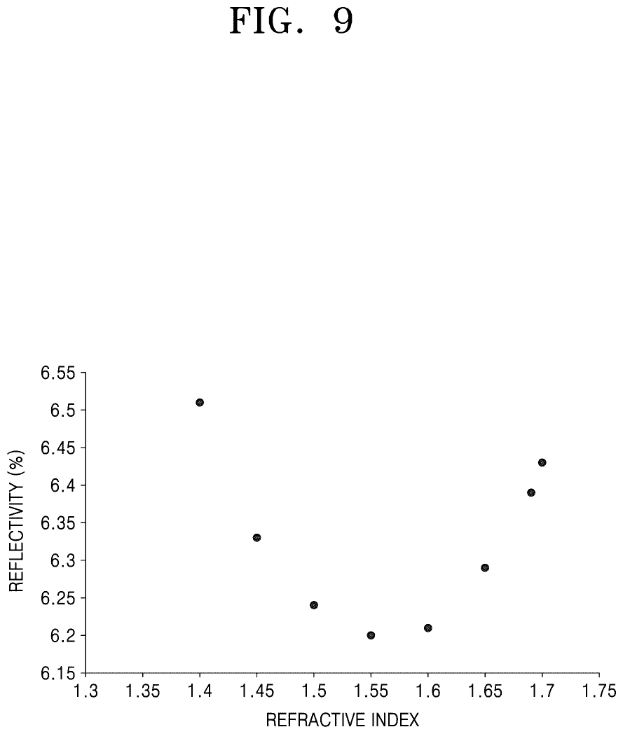

FIG. 9 is a graph illustrating the reflectivity of the display apparatus 1 according to the refractive index of an adhesive layer. Specifically, FIG. 9 is a graph illustrating the reflectivity of the foldable area FA according to the refractive index of the first adhesive layer A1 and the refractive index of the second adhesive layer A2. The horizontal axis of the graph of FIG. 9 represents the refractive index of the first adhesive layer A1 and the refractive index of the second adhesive layer A2, and the vertical axis of the graph of FIG. 9 represents the reflectivity of the foldable area FA of the display apparatus 1. The thickness of the first adhesive layer A1 is 150 nm, and the thickness of the second adhesive layer A2 is 150 nm. The refractive index of the window W is 1.50, and the thickness of the window W is 50 μm. The refractive index of the window protection layer WP is 1.60, and the thickness of the window protection layer WP is 50 μm. The refractive index of the hard coating layer HC is 1.45, and the thickness of the hard coating layer HC is 5 μm.

As illustrated in FIG. 9, when the refractive index of the first adhesive layer A1 and the refractive index of the second adhesive layer A2 are about 1.5 to about 1.6, the reflectivity of the foldable area FA is the lowest. In contrast, for example, when the refractive index of the first adhesive layer A1 and the refractive index of the second adhesive layer A2 are less than 1.5 or more than 1.6, the reflectivity of the foldable area FA rapidly increases. Therefore, when the refractive index of the first adhesive layer A1 is about 1.5 to about 1.6, the crease of the foldable area FA may be less visible.

Although it is illustrated in FIG. 7 that the thickness of the first adhesive layer A1 in the foldable area FA is different from the thickness of the first adhesive layer A1 in the non-folding area, the disclosure is not limited thereto.

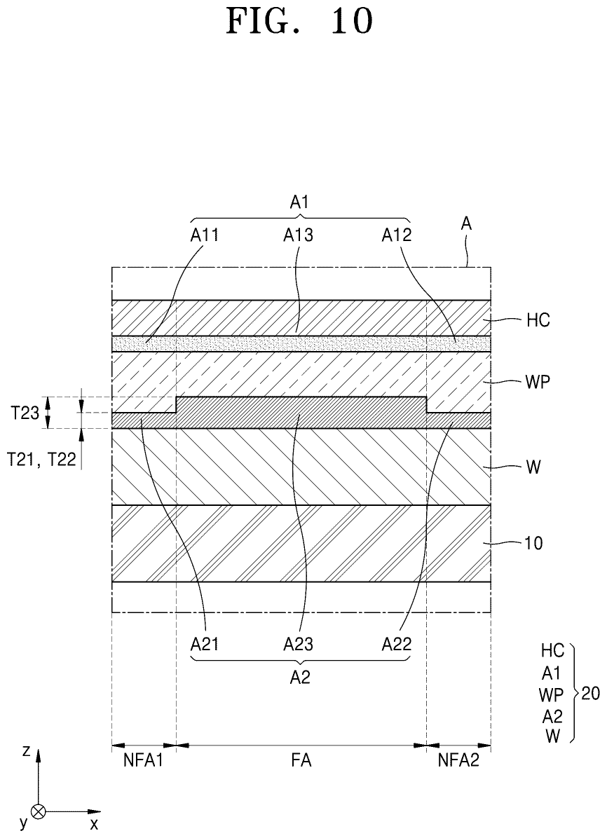

FIG. 10 is a schematic cross-sectional view of a portion of a display apparatus 1 according to an embodiment. Because the display apparatus 1 according to the present embodiment is similar to the display apparatus 1 described herein with reference to FIGS. 1 to 7, the following description will focus on the differences from the display apparatus 1 described herein with reference to FIGS. 1 to 7. That is, FIG. 10 corresponds to FIG. 7. In FIG. 10, the same reference numerals as those in FIGS. 1 to 7 indicate the same members as those in FIGS. 1 to 7, and thus, duplicate descriptions thereof are omitted.

The display apparatus 1 according to an embodiment described herein with reference to FIGS. 1 to 7 includes the display panel 10 and the cover window 20, and the cover window 20 includes the window W, the window protection layer WP, the hard coating layer HC, the first adhesive layer A1, and the second adhesive layer A2. The display apparatus 1 according to the present embodiment also includes the display panel 10 and the cover window 20, and the cover window 20 includes the window W, the window protection layer WP, the hard coating layer HC, the first adhesive layer A1, and the second adhesive layer A2.

However, in the case of the display apparatus 1 according to the present embodiment, the thickness of the first-3 portion A13 may be the same as or similar to the thickness of each of the first-1 portion A11 and the first-2 portion A12. That is, the thicknesses of the first-1 portion A11, the first-2 portion A12, and the first-3 portion A13 may be the same or similar to each other. Specifically, the thickness of each of the first-1 portion A11, the first-2 portion A12, and the first-3 portion A13 may be about 150 nm to about 200 nm.

In this case, the thickness of the second adhesive layer A2 in the foldable area FA may be different from the thickness of the second adhesive layer A2 in the non-folding area. Specifically, the thickness of the second-3 portion A23 may be greater than the thickness of each of the second-1 portion A21 and the second-2 portion A22. That is, the second-1 portion A21 may have a second-1 thickness T21, the second-2 portion A22 may have the second-2 thickness T22, and the second-2 thickness T22 may be the same as or similar to the second-1 thickness T21. The second-3 portion A23 may have a second-3 thickness T23, and the second-3 thickness T23 may be greater than each of the second-1 thickness T21 and the second-2 thickness T22.

For example, each of the second-1 thickness T21 and the second-2 thickness T22 may be about 150 nm to about 200 nm, and the second-3 thickness T23 may be about 250 nm to about 400 nm. Even in this case, the reflectivity of the foldable area FA of the display apparatus 1 may be less than the reflectivity of the non-folding area of the display apparatus 1. Specifically, the reflectivity of the foldable area FA of the display apparatus 1 may be about 6.0% to about 6.7%, and the reflectivity of the non-folding area of the display apparatus 1 may be about 6.3% to about 6.8%. Accordingly, the crease in the foldable area FA may be less visible to the user, and the display quality of the display apparatus 1 may be improved.

Although it is illustrated in FIGS. 7 and 10 that the thickness of one of the first adhesive layer A1 and the second adhesive layer A2 is different between the foldable area FA and the non-folding area, the disclosure is not limited thereto.

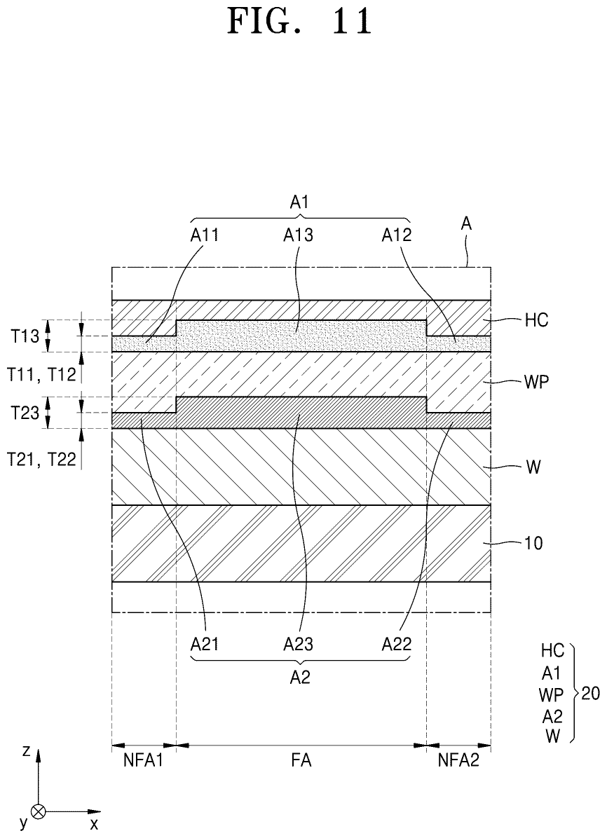

FIG. 11 is a schematic cross-sectional view of a portion of a display apparatus 1 according to an embodiment. Because the display apparatus 1 according to the present embodiment is similar to the display apparatus 1 described herein with reference to FIGS. 1 to 7, the following description will focus on the differences from the display apparatus 1 described herein with reference to FIGS. 1 to 7. That is, FIG. 11 corresponds to FIG. 7. In FIG. 11, the same reference numerals as those in FIGS. 1 to 7 indicate the same members as those in FIGS. 1 to 7, and thus, duplicate descriptions thereof are omitted.

The display apparatus 1 according to an embodiment described herein with reference to FIGS. 1 to 7 includes the display panel 10 and the cover window 20, and the cover window 20 includes the window W, the window protection layer WP, the hard coating layer HC, the first adhesive layer A1, and the second adhesive layer A2. The first adhesive layer A1 includes a first-1 portion A11, a first-2 portion A12, and a first-3 portion A13, and the thickness of the first-3 portion A13 is greater than the thickness of each of the first-1 portion A11 and the first-2 portion A12. Specifically, each of the first-1 thickness T11 and the first-2 thickness T12 is about 150 nm to about 200 nm, and the first-3 thickness T13 is about 250 nm to about 400 nm.

The display apparatus 1 according to the present embodiment also includes the display panel 10 and the cover window 20, and the cover window 20 includes the window W, the window protection layer WP, the hard coating layer HC, the first adhesive layer A1, and the second adhesive layer A2. The first adhesive layer A1 includes a first-1 portion A11, a first-2 portion A12, and a first-3 portion A13, and the thickness of the first-3 portion A13 is greater than the thickness of each of the first-1 portion A11 and the first-2 portion A12. Specifically, the first-1 thickness T11 and the first-2 thickness T12 are each about 150 nm to about 200 nm, and the first-3 thickness T13 is about 250 nm to about 400 nm.

However, in the case of the display apparatus 1 according to the present embodiment, the thickness of the second-3 portion A23 is greater than the thickness of each of the second-1 portion A21 and the second-2 portion A22. Specifically, the second-1 thickness T21 of the second-1 portion A21 and the second-2 thickness T22 of the second-2 portion A22 are each about 150 nm to about 200 nm, and the second-3 thickness T23 of the second-3 portion A23 is about 250 nm to about 400 nm. Even in this case, the reflectivity of the foldable area FA of the display apparatus 1 may be less than the reflectivity of the non-folding area of the display apparatus 1. Specifically, the reflectivity of the foldable area FA of the display apparatus 1 may be about 5.1% to about 6.5%, and the reflectivity of the non-folding area of the display apparatus 1 may be about 6.3% to about 6.8%. Therefore, the crease in the foldable area FA may be less visible to the user, and the display quality of the display apparatus 1 may be improved.

According to embodiments of the disclosure as described herein, a display apparatus having improved display quality and an electronic apparatus including the display apparatus may be implemented. However, the scope of the disclosure is not limited by these effects.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel comprising a display element;
a window arranged on the display panel;
a window protection layer arranged on the window;
a hard coating layer arranged on the window protection layer;
a first adhesive layer arranged between the window protection layer and the hard coating layer; and
a second adhesive layer arranged between the window and the window protection layer,
wherein:
the display panel comprises a first non-folding area, a second non-folding area, and a foldable area between the first non-folding area and the second non-folding area,
the first adhesive layer comprises a first-1 portion overlapping the first non-folding area, a first-2 portion overlapping the second non-folding area, and a first-3 portion overlapping the foldable area, and
a thickness of the first-3 portion is greater than a thickness of each of the first-1 portion and the first-2 portion.

2. The display apparatus of claim 1, wherein:
the thickness of the first-3 portion is about 250 nm to about 400 nm, and
the thickness of each of the first-1 portion and the first-2 portion is about 150 nm to about 200 nm.

3. The display apparatus of claim 1, wherein the first-1 portion, the first-2 portion, and the first-3 portion are integrally provided as a single body.

4. The display apparatus of claim 1, wherein a refractive index of the first adhesive layer is about 1.5 to about 1.6.

5. The display apparatus of claim 1, wherein:
the second adhesive layer comprises a second-1 portion overlapping the first non-folding area, a second-2 portion overlapping the second non-folding area, and a second-3 portion overlapping the foldable area, and
the thicknesses of the second-1 portion, the second-2 portion, and the second-3 portion are equal to each other.

6. The display apparatus of claim 5, wherein:
the thickness of each of the second-1 portion, the second-2 portion, and the second-3 portion is about 150 nm to about 200 nm, and
a refractive index of the second adhesive layer is about 1.5 to about 1.6.

7. A display apparatus comprising:
a display panel comprising a display element;
a window arranged on the display panel;
a window protection layer arranged on the window;
a hard coating layer arranged on the window protection layer;
a first adhesive layer arranged between the window protection layer and the hard coating layer; and
a second adhesive layer arranged between the window and the window protection layer,
wherein:
the display panel comprises a first non-folding area, a second non-folding area, and a foldable area between the first non-folding area and the second non-folding area,
the second adhesive layer comprises a second-1 portion overlapping the first non-folding area, a second-2 portion overlapping the second non-folding area, and a second-3 portion overlapping the foldable area, and
a thickness of the second-3 portion is greater than a thickness of each of the second-1 portion and the second-2 portion.

8. The display apparatus of claim 7, wherein:
the thickness of the second-3 portion is about 250 nm to about 400 nm, and
the thickness of each of the second-1 portion and the second-2 portion is about 150 nm to about 200 nm.

9. The display apparatus of claim 7, wherein the second-1 portion, the second-2 portion, and the second-3 portion are integrally provided as a single body.

10. The display apparatus of claim 7, wherein a refractive index of the second adhesive layer is about 1.5 to about 1.6.

11. The display apparatus of claim 7, wherein:
the first adhesive layer comprises a first-1 portion overlapping the first non-folding area, a first-2 portion overlapping the second non-folding area, and a first-3 portion overlapping the foldable area, and
the thicknesses of the first-1 portion, the first-2 portion, and the first-3 portion are equal to each other.

12. The display apparatus of claim 11, wherein:
the thickness of each of the first-1 portion, the first-2 portion, and the first-3 portion is about 150 nm to about 200 nm, and
a refractive index of the first adhesive layer is about 1.5 to about 1.6.

13. The display apparatus of claim 7, wherein:
the first adhesive layer comprises a first-1 portion overlapping the first non-folding area, a first-2 portion overlapping the second non-folding area, and a first-3 portion overlapping the foldable area, and
a thickness of the first-3 portion is greater than a thickness of each of the first-1 portion and the first-2 portion.

14. The display apparatus of claim 13, wherein:
the thickness of the first-3 portion is about 250 nm to about 400 nm, and
the thickness of each of the first-1 portion and the first-2 portion is about 150 nm to about 200 nm.

15. The display apparatus of claim 13, wherein the first-1 portion, the first-2 portion, and the first-3 portion are integrally provided as a single body.

16. The display apparatus of claim 13, wherein a refractive index of the first adhesive layer is about 1.5 to about 1.6.

17. The display apparatus of claim 13, wherein:
the thickness of the second-3 portion is about 250 nm to about 400 nm, and
the thickness of each of the second-1 portion and the second-2 portion is about 150 nm to about 200 nm.

18. The display apparatus of claim 13, wherein the second-1 portion, the second-2 portion, and the second-3 portion are integrally provided as a single body.

19. The display apparatus of claim 13, wherein a refractive index of the second adhesive layer is about 1.5 to about 1.6.

20. An electronic apparatus comprising:
a display apparatus; and
a housing configured to accommodate the display apparatus and form an appearance of the electronic apparatus,
wherein the display apparatus comprises:
a display panel comprising a display element;
a window arranged on the display panel;
a window protection layer arranged on the window;
a hard coating layer arranged on the window protection layer;
a first adhesive layer arranged between the window protection layer and the hard coating layer; and
a second adhesive layer arranged between the window and the window protection layer,
wherein:
the display panel comprises a first non-folding area, a second non-folding area, and a foldable area between the first non-folding area and the second non-folding area,
the first adhesive layer comprises a first-1 portion overlapping the first non-folding area, a first-2 portion overlapping the second non-folding area, and a first-3 portion overlapping the foldable area, and
a thickness of the first-3 portion is greater than a thickness of each of the first-1 portion and the first-2 portion.
